(19) United States
(12) Patent Application Publication
(10) Pub. No.: US 2026/0164896 A1
(43) Pub. Date: Jun. 11, 2026

(54) DISPLAY APPARATUS, ELECTRONIC APPARATUS INCLUDING DISPLAY APPARATUS, AND METHOD OF MANUFACTURING DISPLAY APPARATUS

(71) Applicant: Samsung Display Co., LTD., Yongin-si (KR)

(72) Inventors: Hyungil Jeon, Yongin-si (KR); Gyujeong Lee, Yongin-si (KR); Changil Tae, Yongin-si (KR)

(21) Appl. No.: 19/179,479

(22) Filed: Apr. 15, 2025

(30) Foreign Application Priority Data
Oct. 29, 2024 (KR) 10-2024-0149989

(51) Int. Cl. H10H 29/85; H10H 29/01; H10K 59/12; H10K 77/10; H10K 102/00

(52) U.S. Cl. CPC H10H 29/8508; H10H 29/0362; H10K 59/1201; H10K 77/10; H10K 2102/311

(57) ABSTRACT

Provided is a display apparatus including a mask layer including a first mask layer and a second mask layer disposed apart from each other, a substrate disposed on the first mask layer and the second mask layer, a pixel circuit layer which is disposed on the substrate and overlaps the first mask layer, a wiring layer which is disposed on the substrate and overlaps the second mask layer, and a light-emitting diode which is disposed on the pixel circuit layer.

### CROSS-REFERENCE TO RELATED APPLICATION

This application claims priority to Korean Patent Application No. 10-2024-0149989, filed on Oct. 29, 2024, and all the benefits accruing therefrom under 35 U.S.C. § 119, the content of which in its entirety is herein incorporated by reference.

### BACKGROUND

### 1. Field

One or more embodiments relate to a display apparatus, for example, a flexible display apparatus.

### 2. Description of the Related Art

With the development of display apparatuses that visually display various electrical signals, various display apparatuses having excellent characteristics such as, for example, being thin, being lightweight, having low power consumption, and the like have been introduced. As an example, flexible display apparatuses that are foldable or rollable in a roll shape have been introduced. Recently, research and development into display apparatuses of various structures, such as, for example, stretchable display apparatuses that may change into various shapes are actively in progress.

### SUMMARY

One or more embodiments include a display apparatus, for example, a flexible display apparatus. However, such a technical objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a mask layer including a first mask layer and a second mask layer disposed apart from each other, a substrate disposed on the first mask layer and the second mask layer, a pixel circuit layer which is disposed on the substrate and overlaps the first mask layer, a wiring layer which is disposed on the substrate and overlaps the second mask layer, and a light-emitting diode disposed on the pixel circuit layer.

In an embodiment, in a cross-sectional view, a width of the first mask layer may be equal to a width of the pixel circuit layer.

In an embodiment, in a cross-sectional view, a width of the second mask layer may be equal to a width of the wiring layer.

In an embodiment, the substrate may include a first base layer, and a first barrier layer disposed on the first base layer.

In an embodiment, the first barrier layer may be in contact with the pixel circuit layer, and the first base layer may be in contact with the mask layer.

In an embodiment, the substrate may further include a second base layer disposed on the first barrier layer, and a second barrier layer disposed on the second base layer, wherein the second barrier layer may be in contact with the pixel circuit layer, and the first base layer may be in contact with the mask layer.

In an embodiment, an etching selectivity of the first base layer with respect to the mask layer may be 40 or more.

In an embodiment, the first barrier layer may overlap the first mask layer and be apart from the second mask layer.

In an embodiment, the mask layer may include at least one of a transparent conductive oxide (TCO), metal, or a silicon oxide.

According to one or more embodiments, an electronic apparatus includes a mask layer including a first mask layer and a second mask layer disposed apart from each other, a substrate disposed on the first mask layer and the second mask layer, a pixel circuit layer which is disposed on the substrate and overlaps the first mask layer, a wiring layer which is disposed on the substrate and overlaps the second mask layer, and a light-emitting diode disposed on the pixel circuit layer, wherein, in a cross-sectional view, a width of the first mask layer is equal to a width of the pixel circuit layer, and a width of the second mask layer is equal to a width of the wiring layer.

According to one or more embodiments, a method of manufacturing a display apparatus includes disposing a first layer on a carrier substrate, disposing a first mask layer on the first layer, disposing, on the first layer, a second mask layer which is apart from the first mask layer, disposing, on the first layer, a substrate which covers the first mask layer and the second mask layer, disposing, on the substrate, a pixel circuit layer which overlaps the first mask layer, disposing, on the substrate, a wiring layer which overlaps the second mask layer, disposing a light-emitting diode on the pixel circuit layer, disposing a carrier film on the light-emitting diode, removing the carrier substrate, etching the first layer, etching the substrate such that a portion of the substrate apart from the first mask layer and the second mask layer is removed, and removing the carrier film.

In an embodiment, the disposing of the substrate may include disposing a first base layer on the first mask layer and the second mask layer, and disposing, on the first base layer, a first barrier layer which overlaps the first mask layer.

In an embodiment, an etching selectivity of the first base layer with respect to the first mask layer may be 40 or more.

In an embodiment, the disposing of the substrate may further include disposing, on the first base layer, a second base layer which covers the first barrier layer, and disposing, on the second base layer, a second barrier layer which overlaps the first mask layer.

In an embodiment, the method may further include attaching a first encapsulation layer to the first mask layer and the second mask layer, and disposing a second encapsulation layer on the light-emitting diode.

In an embodiment, the disposing of the first mask layer and the disposing of the second mask layer may be simultaneously performed.

In an embodiment, the disposing of the pixel circuit layer and the disposing of the wiring layer may be simultaneously performed.

In an embodiment, the etching of the first layer and the etching of the substrate may be simultaneously performed.

In an embodiment, in a cross-sectional view, a width of the first mask layer may be equal to a width of the pixel circuit layer.

In an embodiment, in a cross-sectional view, a width of the second mask layer may be equal to a width of the wiring layer.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIGS. 2A and 2B are perspective views of the display apparatus of FIG. 1 stretched in a first direction;

FIG. 2C is a perspective view of the display apparatus of FIG. 1 stretched in a second direction;

FIG. 2D is a perspective view of the display apparatus of FIG. 1 stretched in the first direction and the second direction;

FIG. 2E is a perspective view illustrating of the display apparatus of FIG. 1 stretched in a third direction;

FIG. 3 is a schematic plan view of a display apparatus according to an embodiment;

FIG. 4A is an enlarged plan view of a portion of a display apparatus, illustrating a region IV of FIG. 3 according to an embodiment;

FIG. 4B is an enlarged plan view of a portion of a display apparatus, illustrating a region IV of FIG. 3 according to an embodiment;

FIG. 4C is an enlarged plan view of a portion of a display apparatus, illustrating a region IV of FIG. 3 according to an embodiment;

FIG. 5 is a schematic cross-sectional view of a first island portion and a first bridge portion disposed in a display area of a display apparatus according to an embodiment;

FIGS. 6A to 6C are equivalent circuit diagrams of a sub-pixel of a display apparatus according to an embodiment;

FIG. 7A is a schematic cross-sectional view of a light-emitting element of a display apparatus according to an embodiment;

FIG. 7B is a schematic cross-sectional view of a light-emitting element of a display apparatus according to an embodiment;

FIG. 8A is an enlarged plan view of a first island portion of a display apparatus according to an embodiment;

FIG. 8B is a plan view of an arrangement of a wiring on a first bridge portion of a display apparatus according to an embodiment;

FIGS. 9 and 10 are schematic cross-sectional views of a display apparatus according to an embodiment;

FIG. 11 is a schematic flowchart illustrating a method of manufacturing a display apparatus according to an embodiment;

FIGS. 12A to 12E are schematic cross-sectional views of a display apparatus according to an embodiment; and

FIGS. 13A to 13G are schematic perspective views of an electronic apparatus including a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to provide examples explaining aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described herein in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element illustrated in the drawings are arbitrarily represented for convenience of description, and thus, the disclosure is not necessarily limited thereto.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

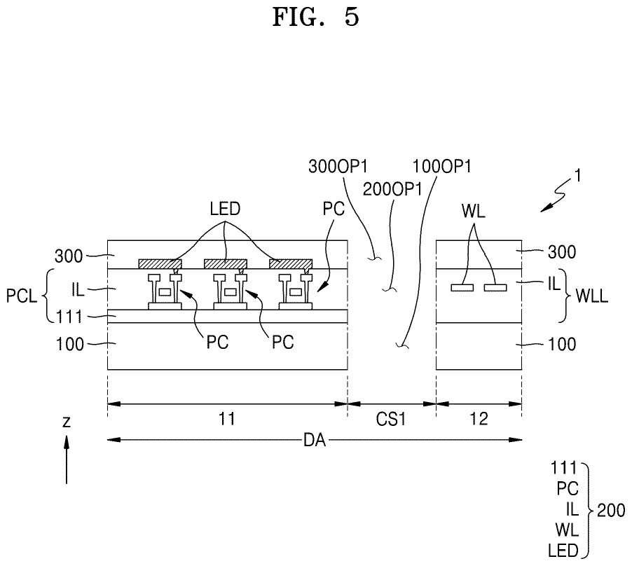

In the present specification, “on a plane” means a plane viewed from a direction perpendicular to a substrate 100 (see FIG. 5). That is, “A and B apart from each other on a plane” means “A and B apart from each other when viewed in a direction perpendicular to the substrate 100 (see FIG. 5).”

In the present specification, “in a cross-section” means a plane cut in a direction perpendicular to the substrate 100 (see FIG. 5). That is, “in a cross-sectional view, A and B apart from each other” means “A and B apart from each other in a plane cut in a direction perpendicular to the substrate 100 (see FIG. 5).”

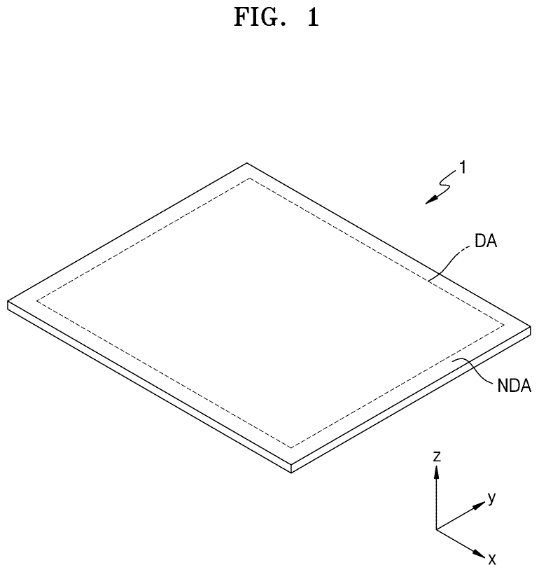

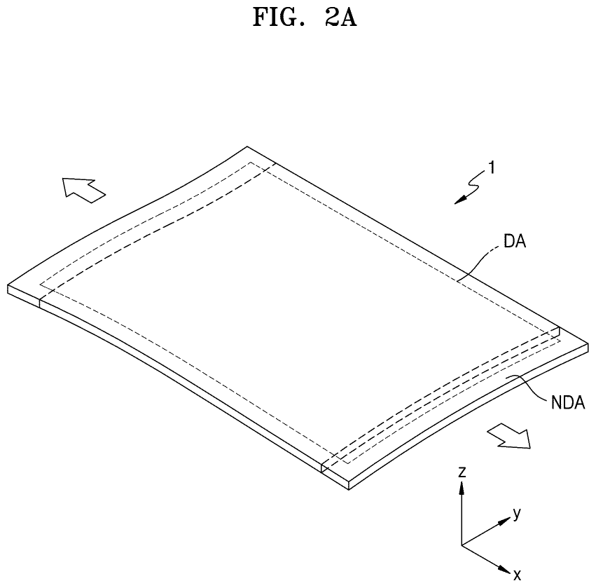

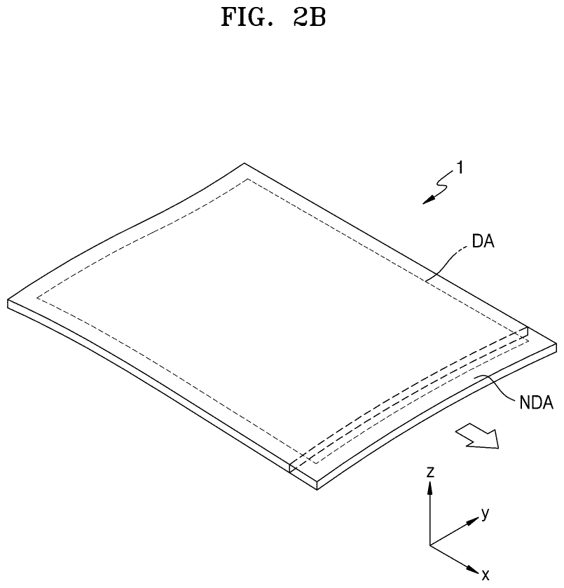

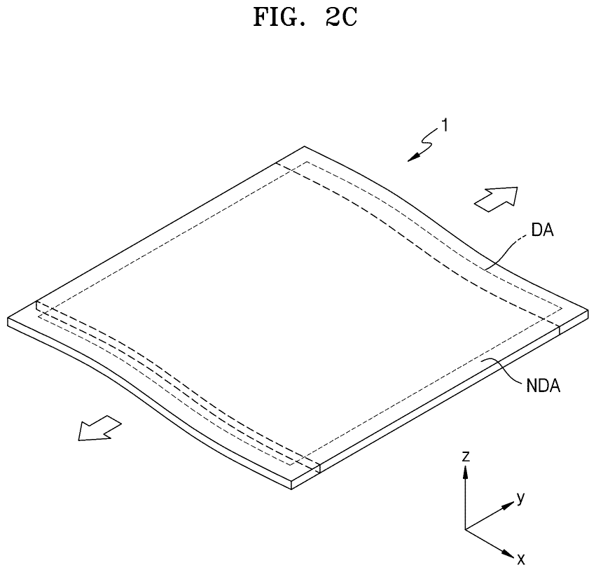

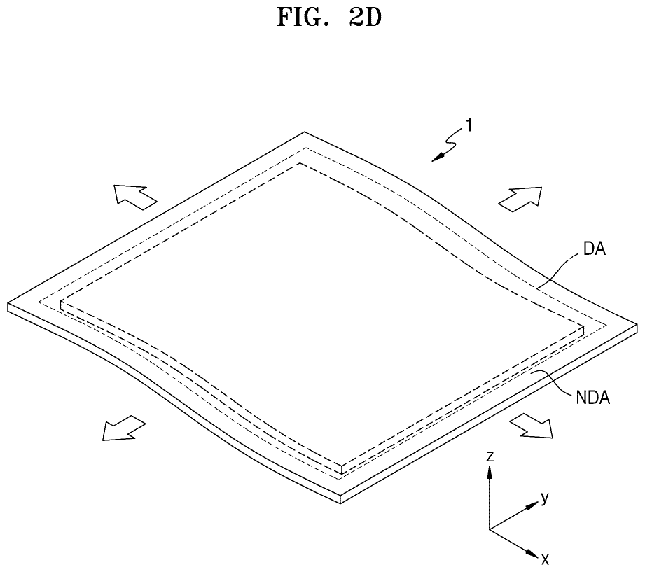

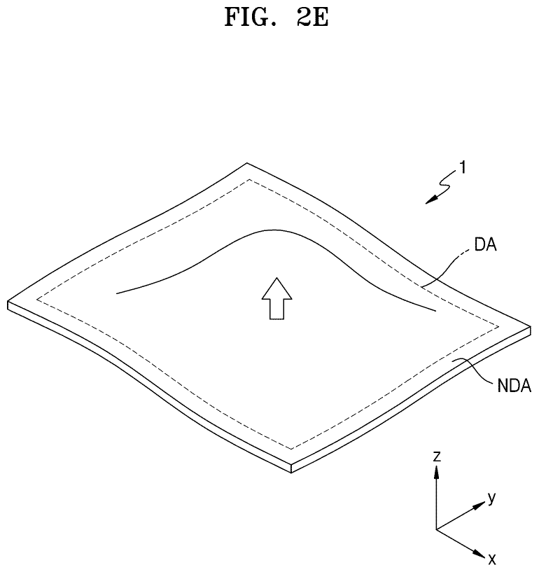

FIG. 1 is a schematic perspective view of a display apparatus 1 according to an embodiment. FIGS. 2A and 2B are perspective views of the display apparatus 1 of FIG. 1 stretched in a first direction (e.g., x direction and/or −x direction). FIG. 2C is a perspective view of the display apparatus 1 of FIG. 1 stretched in a second direction (e.g., y direction and/or −y direction). FIG. 2D is a perspective view of the display apparatus 1 of FIG. 1 stretched in the first direction (e.g., x direction and/or −x direction) and the second direction (e.g., y direction and/or −y direction). FIG. 2E is a perspective view of the display apparatus 1 of FIG. 1 stretched in a third direction (e.g., z direction and/or −z direction).

Referring to FIG. 1, the display apparatus 1 may include a display area DA and a non-display area NDA. The display area DA may include a plurality of pixels. The display apparatus 1 may be configured to display images by using light emitted from the plurality of pixels. The non-display area NDA may be disposed outside the display area DA. The non-display area NDA may surround the display area DA entirely.

The display apparatus 1 may stretch or shrink in various directions. The display apparatus 1 may be stretched in the first direction (e.g., x direction and/or −x direction) by external force exerted by an external object or a user. In an embodiment, as illustrated in FIGS. 2A and 2B, the display area DA and/or the non-display area NDA of the display apparatus 1 may be stretched in the first direction (e.g., x direction and/or −x direction). As an example, as illustrated in FIG. 2A, the display area DA and/or the non-display area NDA may be stretched in the x direction and −x direction, or as illustrated in FIG. 2B, be stretched in the x direction with one side of the display apparatus 1 fixed.

The display apparatus 1 may be stretched in the second direction (e.g., y direction and/or −y direction) by external force exerted by an external object or a user. In an embodiment, as illustrated in FIG. 2C, the display area DA and/or the non-display area NDA of the display apparatus 1 may be stretched in the y direction and −y direction. In another embodiment, the display apparatus 1 may be stretched in the y direction or −y direction with one side of the display apparatus 1 fixed.

The display apparatus 1 may be stretched in a plurality of directions, for example, the first direction (e.g., x direction and/or −x direction) and the second direction (e.g., y direction and/or −y direction) by external force exerted by an external object or a portion of a person's body. As illustrated in FIG. 2D, the display area DA and/or the non-display area NDA of the display apparatus 1 may be stretched in a ±x direction and ±y direction.

The display apparatus 1 may be stretched in a third direction (e.g., z direction and/or −z direction) by external force exerted by an external object or a portion of a person's body. In an embodiment, FIG. 2E illustrates a portion of the display apparatus 1, for example, a partial region of the display area DA protrudes in the z direction. In another embodiment, a portion of the display apparatus 1, for example, a partial region of the display area DA may protrude in the −z direction (or be recessed in the z direction).

Although it is illustrated in FIGS. 2A to 2E that the display apparatus 1 is stretched in the first direction, the second direction, and/or the third direction, the disclosure is not limited thereto. In another embodiment, the display apparatus 1 may be variously transformed into an irregular shape, such as, for example, by being bent or twisted along two or more axes.

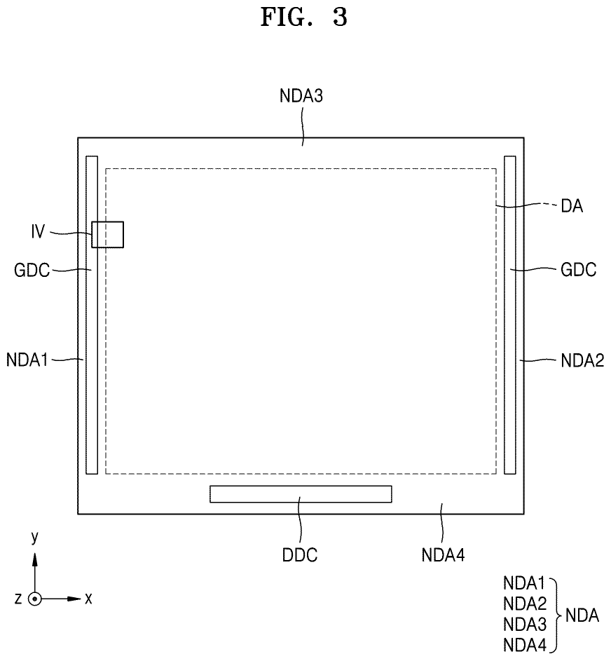

FIG. 3 is a schematic plan view of the display apparatus 1 according to an embodiment.

The plurality of pixels may be arranged in the display area DA of the display apparatus 1. Each pixel may include sub-pixels emitting light of different colors. A light-emitting element corresponding to each sub-pixel may be disposed in the display area DA. A circuit may be located in the non-display area NDA around the display area DA, wherein the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of transistors electrically connected to light-emitting elements. Although it is illustrated in FIG. 3 that the gate driving circuit GDC is disposed in each of the first non-display area NDA1 and the second non-display area NDA2, the disclosure is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, it is illustrated in FIG. 3 that the data driving circuit DDC is disposed in the fourth non-display area NDA4. In another embodiment, the data driving circuit DDC may be disposed in each of the third non-display area NDA3 and fourth non-display area NDA4.

Although it is illustrated in FIG. 3 that the data driving circuit DDC is disposed in the fourth non-display area NDA4 of the display apparatus 1, the disclosure is not limited thereto. In another embodiment, the display apparatus 1 may further include a flexible circuit board (not illustrated) electrically connected through a terminal section (not illustrated) disposed in the fourth non-display area NDA4, and the data driving circuit DDC may be disposed on the flexible circuit board.

In another embodiment, an elongation rate of the non-display area NDA may be equal to or less than an elongation rate of the display area DA. In an embodiment, an elongation rate of the non-display area NDA may be different for each region of the non-display area NDA. As an example, the first non-display area NDA1, the second non-display area NDA2, and the third non-display area NDA3 may have the substantially same elongation rate, but an elongation rate of the fourth non-display area NDA4 may be less than an elongation rate of each of the first non-display area NDA1, the second non-display area NDA2, and the third non-display area NDA3.

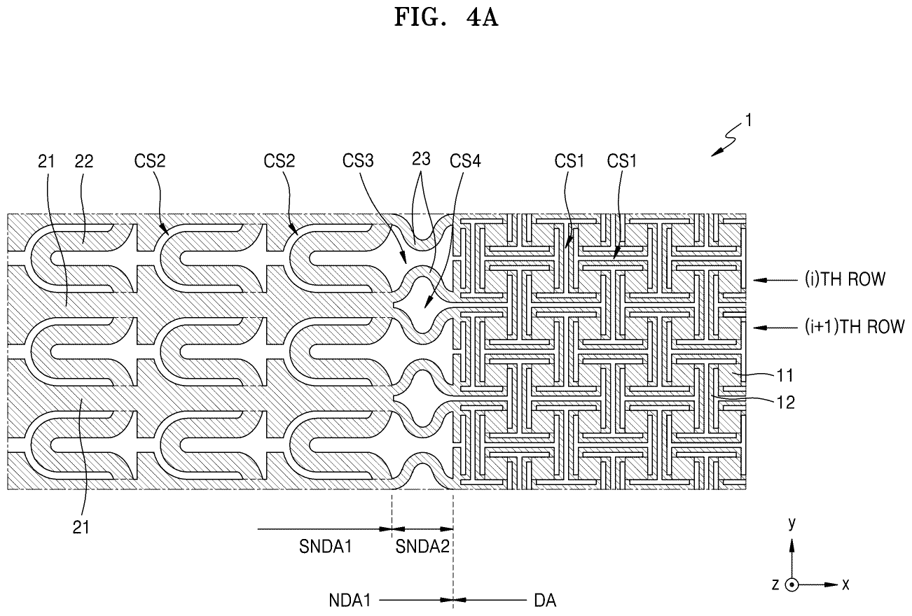

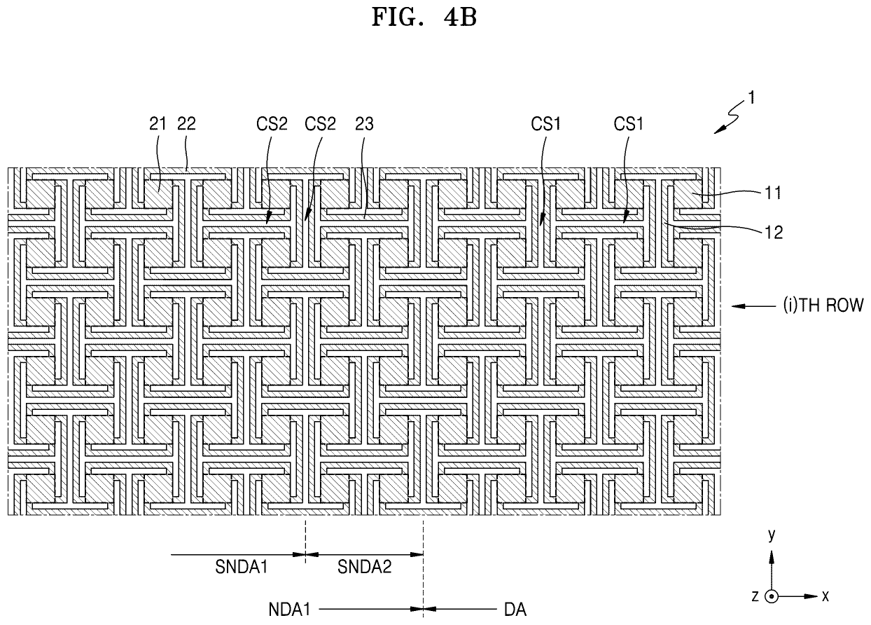

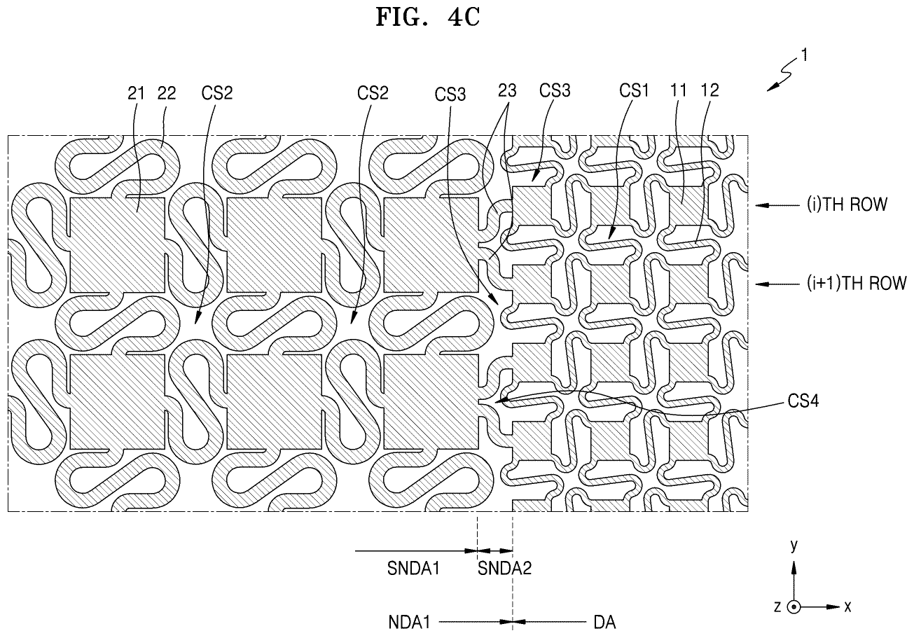

FIG. 4A is an enlarged plan view of a portion of the display apparatus 1, illustrating a region IV of FIG. 3 according to an embodiment.

Referring to FIG. 4A, the display apparatus 1 may include first island portions 11 and first bridge portions 12 connecting adjacent island portions 11, wherein the first island portions 11 are apart from each other in the first direction (e.g., x direction or −x direction) and the second direction (e.g., y direction or −y direction) in the display area DA.

Each of the first island portions 11 may be connected to a plurality of first bridge portions 12. As an example, each of the first island portions 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). In an embodiment, four first bridge portions 12 may be respectively connected to four sides of the first island portion 11. Four first bridge portions 12 may be respectively adjacent to the corners of the first island portion 11.

The first bridge portions 12 may be apart from each other by a first opening CS1 located between the first bridge portions 12. In an embodiment, a first opening CS1 having an approximate H shape and a first opening CS1 having an approximate I shape that is obtained by rotating the H shape by 90° may be alternately repeatedly arranged in the first direction (e.g., x direction or −x direction) and the second direction (e.g., y direction or −y direction). Two opposite ends of each of the first bridge portions 12 are respectively connected to adjacent first island portions 11, and one side of each of the first bridge portions 12 may be apart from one side of an adjacent first island portion 11 and/or one side of another first bridge portion 12 by the first opening CS1.

The display apparatus 1 may include second island portions 21 apart from each other, and second bridge portions 22 connecting adjacent second island portions 21 in the non-display area, for example, the first non-display area NDA1 illustrated in FIG. 4A.

Each of the second island portions 21 may extend in the first direction (e.g., x direction or −x direction). The second island portions 21 may be apart from each other in the second direction (e.g., the y direction or the −y direction) crossing the first direction (e.g., x direction or −x direction). Each of the second island portions 21 may include drivers of the gate driving circuit GDC (see FIG. 4A) described with reference to FIG. 3.

The second bridge portion 22 may have a serpentine shape. The length of the second bridge portion 22 may be greater than the shortest distance between adjacent second island portions 21 in the second directions (e.g., y direction or −y direction). In an embodiment, the second bridge portion 22 may have an approximate omega (Ω) shape convex toward the first direction (e.g., x direction or −x direction). The second bridge portions 22 may be disposed between adjacent second island portions 21 and be apart from each other.

The second bridge portions 22 between adjacent second island portions 21 may be apart from each other by a second opening CS2. Between adjacent second island portions 21, the second openings CS2 and the second bridge portions 22 may be alternately arranged in the first direction (e.g., x direction or −x direction). The second openings CS2 may have the same shape. Two opposite ends of each of the second bridge portions 22 are respectively connected to adjacent second island portions 21, and one side of each of the second bridge portions 22 may be apart from one side of an adjacent second island portion 21 and/or one side of another second bridge portion 22 by the second opening CS2.

One of the second island portions 21 disposed in the first non-display area NDA1 may correspond to first island portions 11 in a plurality of rows arranged in the display area DA. As an example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive integer greater than 0). Although it is illustrated in FIG. 4A that the second island portion 21 corresponds to two rows of the first island portions 11, the disclosure is not limited thereto. In another embodiment, one of second island portions 21 disposed in the first non-display area NDA1 may correspond to n rows of the first island portions 11 disposed in the display area DA (here, i is a positive integer equal to or greater than 3).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, wherein the third bridge portions 23 connect the display area DA to the first sub-non-display area SNDA1. One end of the third bridge portion 23 may be connected to the second island portion 21 and/or second bridge portion 22, and the other end of the third bridge portion 23 may be connected to the first island portion 11 and/or first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as illustrated in FIG. 4A, the third bridge portion 23 may have an approximate omega (Ω) shape convex toward the second direction (e.g., y direction or −y direction). The third bridge portions 23 may have a symmetrical structure in which one of adjacent third bridge portions 23 arranged in the second direction (e.g., y direction or −y direction) may be convex in y direction and another may be convex in −y direction. Between the third bridge portions 23, a structure in which a third opening CS3 and a fourth opening CS4 having different shapes are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

It is illustrated in FIG. 4A that the second island portion 21 and the second bridge portion 22 in the non-display area, for example, the first non-display area NDA1, respectively have shapes different from the shapes of the first island portion 11 and the first bridge portion 12 in the display area DA. In another embodiment, the second island portion 21 and the second bridge portion 22 in the non-display area may respectively have the same shape as the shape of the first island portion 11 and the first bridge portion 12 in the display area DA.

FIG. 4B is an enlarged plan view of a portion of the display apparatus 1, illustrating a region IV of FIG. 3 according to an embodiment.

Referring to FIG. 4B, the display apparatus 1 includes the first island portions 11 apart from each other in the display area DA, and the first bridge portions 12 apart from each other by the first opening CS1 and connecting adjacent first island portions 11. The structure of the display area DA in FIG. 4B may be the same as the structure of the display area DA described herein with reference to FIG. 4A.

The display apparatus 1 may include the second island portions 21 and the second bridge portions 22 disposed in the non-display area, for example, the first non-display area NDA1. In an embodiment, the second island portions 21 and the second bridge portions 22 may respectively have the same shapes as the shapes of the first island portions 11 and the first bridge portions 12.

The second island portions 21 may be apart from each other in the first direction (e.g., x direction or −x direction) and the second direction (e.g., y direction or −y direction) in the non-display area, for example, the first non-display area NDA1. Each of the second bridge portions 22 may connect adjacent second island portions 21. The second bridge portions 22 may be apart from each other by a second opening CS2 located between the second bridge portions 22.

The second opening CS2 may have the substantially same shape as the shape of the first opening CS1. As an example, the second opening CS2 having an approximate H shape and the second opening CS2 having an approximate I shape may be alternately repeatedly arranged in the non-display area, for example, the first non-display area NDA1. Two opposite ends of each of the second bridge portions 22 are respectively connected to adjacent second island portions 21, and one side of each of the second bridge portions 22 may be apart from one side of an adjacent second island portion 21 and/or one side of another second bridge portion 22 by the second opening CS2.

Each of the second island portions 21 may be connected to four second bridge portions 22. Each of the second island portions 21 may include drivers of the gate driving circuit GDC (see FIG. 4A) described with reference to FIG. 3.

The second island portions 21 in one of rows disposed in the first non-display area NDA1 may correspond to first island portions 11 in one of rows arranged in the display area DA. As an example, the second island portions 21 arranged in an i-th row in the first direction (e.g., x direction or −x direction) in the first non-display area NDA1 may correspond to the first island portions 11 arranged in the same row, for example, the i-th row in the display area DA (here, i is a positive integer greater than 0).

The display apparatus 1 may include the third bridge portions 23 disposed in the second sub-non-display area SNDA2 connecting the display area DA to the first sub-non-display area SNDA1. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially same as the first bridge portion 12 and the second bridge portion 22. As an example, the width of the third bridge portion 23 may be the same as the width of the first bridge portion 12 and the width of the second bridge portion 22.

FIG. 4C is an enlarged plan view of a portion of the display apparatus 1, illustrating a region IV of FIG. 3 according to an embodiment.

Referring to FIG. 4C, the display apparatus 1 may include first island portions 11 and first bridge portions 12 connecting adjacent island portions 11, wherein the first island portions 11 are apart from each other in the first direction (e.g., x direction or −x direction) and the second direction (e.g., y direction or −y direction) in the display area DA.

The first bridge portions 12 may be apart from each other by a first opening CS1 located between the first bridge portions 12. The first bridge portion 12 may have a serpentine shape. As an example, as illustrated in FIG. 4C, the first bridge portion 12 may have an approximate ‘letter S’shape.

Each of the first island portions 11 may be connected to a plurality of first bridge portions 12. As an example, each of the first island portions 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). Four first bridge portions 12 may be respectively connected to four sides of the first island portion 11. Four first bridge portions 12 may be respectively adjacent to the corners of the first island portion 11.

In the non-display area, for example, the first non-display area NDA1 illustrated in FIG. 4C, the display apparatus 1 may include the second island portions 21 apart from each other in the first direction (e.g., x direction or −x direction) and the second direction (e.g., y direction or −y direction), and the second bridge portions 22 connecting the second island portions 21.

The second bridge portions 22 may be apart from each other by a second opening CS2 located between the second bridge portions 22. The second bridge portion 22 may have a serpentine shape. As an example, as illustrated in FIG. 4C, the second bridge portion 22 may have an approximate ‘letter S’ shape. The size and/or width of the second bridge portion 22 may be different from the size and/or width of the first bridge portion 12. As an example, the size and/or width of the second bridge portion 22 may be greater than the size and/or width of the first bridge portion 12. The curvature radius of a round portion of the second bridge portion 22 may be different from the curvature radius of a round portion of the first bridge portion 12. As an example, the curvature radius of a round portion of the second bridge portion 22 may be greater than the curvature radius of a round portion of the first bridge portion 12.

Each of the second island portions 21 may be connected to a plurality of second bridge portions 22. Each of the second island portions 21 may be connected to four second bridge portions 22. Two second bridge portions 12 may be disposed on two opposite sides of the second island portion 21 in the first direction (e.g., x direction or −x direction), and the remaining two second bridge portions 22 may be disposed on two opposite sides of the second island portion 21 in the second direction (e.g., y direction or −y direction). In an embodiment, four second bridge portions 22 may be respectively connected to four sides of the second island portion 21. Each of the second bridge portions 22 may be connected to the central portion of each side of the second island portion 21.

The second island portions 21 in one of rows disposed in the first non-display area NDA1 may correspond to the first island portions 11 in a plurality of rows arranged in the display area DA. As an example, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive integer greater than 0). In another embodiment, the second island portions 21 in one of rows may correspond to n rows of first island portions 11 (here, n is a positive number equal to or greater than 3).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, wherein the third bridge portions 23 connect the display area DA to the first sub-non-display area SNDA1. One end of the third bridge portion 23 may be connected to the second island portion 21, and the other end of the third bridge portion 23 may be connected to the first island portion 11. As an example, one end of the third bridge portion 23 may be connected to the central portion of one side of the second island portion 21, and the other end of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., y direction or −y direction), the third opening CS3 and the fourth opening CS4 having different shapes may be alternately disposed.

FIG. 5 is a schematic cross-sectional view of the first island portion 11 and the first bridge portion 12 disposed in the display area DA of the display apparatus 1 according to an embodiment.

Referring to FIG. 5, the first island portion 11 and the first bridge portion 12 disposed in the display area DA may be apart from each other, with the first opening CS1 between the first island portion 11 and the first bridge portion 12. The first island portion 11 may include light-emitting elements LED and a circuit electrically connected thereto and driving the light-emitting element LED, for example, a pixel driving circuit PC, and the first bridge portions 12 may include a wiring WL electrically connected to the pixel driving circuits PC disposed in each of adjacent first island portions 11.

In the first island portion 11, a buffer layer 111 including an inorganic insulating material may be disposed on the substrate 100, and the pixel driving circuit PC may be disposed on the buffer layer 111. An insulating layer IL including an inorganic insulating material and/or an organic insulating material may be disposed between the pixel driving circuit PC and the light-emitting element LED. The light-emitting element LED may be disposed on the insulating layer IL and electrically connected to the pixel driving circuit PC corresponding thereto. The light-emitting elements LED may emit light of different colors or light of the same color. In an embodiment, the light-emitting elements LED may be configured to emit red, green, or blue light. In an embodiment, the light-emitting elements LED may emit white light. In another embodiment, the light-emitting elements LED may be configured to emit red, green, blue light, or white light.

The substrate 100 may include polymer resin such as, for example, polyethersulfone, polyarylate, polyetherimide, polyethylene naphthalate, polyethylene terephthalate, polyphenylene sulfide, polyimide, polycarbonate, cellulose tri acetate, and cellulose acetate propionate. In an embodiment, the substrate 100 may be a single layer including the polymer resin. In another embodiment, the substrate 100 may have a multi-layered structure including a base layer and a barrier layer, wherein the base layer includes the above polymer resin and the barrier layer includes an inorganic insulating material. The substrate 100 including the polymer resin is flexible, rollable, or bendable.

In an embodiment, although it is illustrated in FIG. 5 that three pixel driving circuits PC are disposed in each of the first island portions 11, and three light-emitting elements LED are respectively connected to the pixel driving circuits PC, the disclosure is not limited thereto. In another embodiment, the number of pixel driving circuits PC and the number of light-emitting elements LED disposed in the first island portion 11 may be one, two, or four or more.

An encapsulation layer 300 may be disposed on the light-emitting element LED and may protect the light-emitting element LED from external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as, for example, resin. In an embodiment, the encapsulation layer 300 may include urethane epoxy acrylate. The encapsulation layer 300 may include a photosensitive material, for example, a photoresist.

In the first bridge portion 12, the insulating layer IL including an organic insulating material may be disposed on the substrate 100. In an example in which the display apparatus 1 stretches, the first bridge portion 12, which is relatively subject to a large amount of transformation, may not have a layer including an inorganic insulating material that is prone to cracking, unlike the first island portion 11.

In an embodiment, the substrate 100 corresponding to the first bridge portion 12 may have the same stack structure as a stack structure of the substrate 100 corresponding to the first island portion 11. In an embodiment, the substrate 100 corresponding to the first bridge portion 12 and the substrate 100 corresponding to the first island portion 11 may be polymer resin layers simultaneously formed during the same process. In another embodiment, the substrate 100 corresponding to the first bridge portion 12 may have a different stack structure from a stack structure of the substrate 100 corresponding to the first island portion 11. In an embodiment, the substrate 100 corresponding to the first island portion 11 may have a multi-layered structure including a base layer that includes a polymer resin and a barrier layer that includes an inorganic insulating material, and the substrate 100 corresponding to the first bridge portion 12 may have a structure of a polymer resin layer in which a layer including an inorganic insulating material is absent.

As described herein, the wirings WL of the first bridge portion 12 may be signal lines (e.g., a gate line, a data line, and the like) configured to provide electrical signals, or voltage lines (e.g., a driving voltage line, an initialization voltage line, and the like) configured to provide voltages to transistors included in the pixel driving circuit PC of the first island portion 11. The encapsulation layer 300 may be disposed on also the first bridge portion 12. In another embodiment, the encapsulation layer 300 may not be present on the first bridge portion 12. Hereinafter, the buffer layer 111, the insulating layer IL, and the pixel driving circuit PC of the first island portion 11 are collectively referred to as a pixel circuit layer PCL, and the insulating layer IL and the wiring WL of the first bridge portion 12 are collectively referred to as a wiring layer WLL.

Referring to FIGS. 4A to 4C and 5, the substrate 100 corresponding to the first island portion 11 may be connected to the substrate 100 corresponding to the first bridge portion 12. In other words, the plan views illustrated in FIGS. 4A to 4C may be substantially same as the plan view of the substrate 100 in FIG. 5. In other words, the substrate 100 may include a region corresponding to the first island portion 11, a region corresponding to the first bridge portion 12, and an opening 100OP1 having the same shape as a shape of the first opening CS1.

Similarly, the encapsulation layer 300 corresponding to the first island portion 11 may be connected to the encapsulation layer 300 corresponding to the first bridge portion 12. As an example, the plan views illustrated in FIGS. 4A to 4C may be substantially same as the plan view of the encapsulation layer 300. In other words, the encapsulation layer 300 may include a region corresponding to the first island portion 11, a region corresponding to the first bridge portion 12, and an opening 300OP1 having the same shape as a shape of the first opening CS1.

A circuit-light-emitting element layer 200 between the substrate 100 and the encapsulation layer 300 may include the buffer layer 111, the pixel driving circuit PC, the wiring WL, the insulating layer IL, and the light-emitting element LED. Similar to the substrate 100, the plan views illustrated in FIGS. 4A to 4C may be substantially same as the plan view of the circuit-light-emitting element layer 200. In other words, the circuit-light-emitting element layer 200 may include an opening 200OP1 having the same shape as a shape of the first opening CS1.

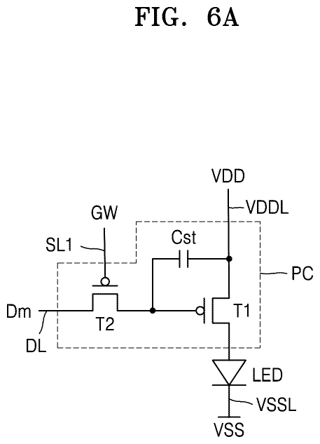

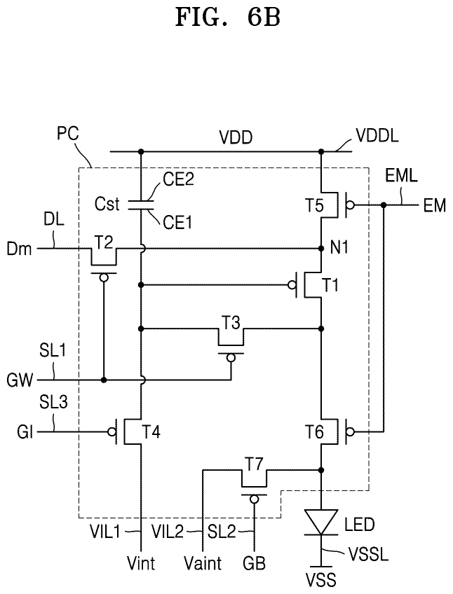

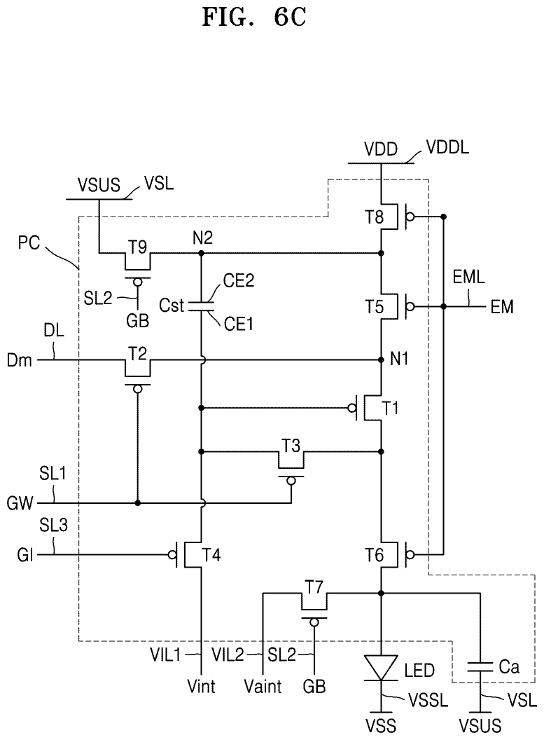

FIGS. 6A to 6C are equivalent circuit diagrams of a sub-pixel of the display apparatus 1 according to an embodiment.

Referring to FIG. 6A, a light-emitting element LED corresponding to a sub-pixel may be electrically connected to the pixel driving circuit PC, and the pixel driving circuit PC may include a first transistor T1, a second transistor T2, and a storage capacitor Cst. The pixel driving circuit PC may be electrically connected to a signal line and a voltage line. The signal line may include a gate line such as, for example, a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 is configured to transfer a data signal Dm to the first transistor T1 according to a first scan signal GW input from the first scan line GL1, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected between the first voltage line VDDL and the storage capacitor Cst. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although it is illustrated in FIG. 6A that the pixel driving circuit PC includes two transistors and one storage capacitor, the pixel driving circuit PC may include three or more transistors in other embodiments.

Referring to FIG. 6B, the pixel driving circuit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit PC is electrically connected to signal lines and voltage lines. The signal lines may include a gate line such as, for example, the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may be configured to transfer a first initialization voltage Vint to the pixel driving circuit PC, wherein the first initialization voltage Vint initializes the first transistor T1. The second initialization voltage line VIL2 may be configured to transfer a second initialization voltage Vaint to the pixel driving circuit PC, wherein the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 serves as a driving transistor, and receives a data signal Dm and supplies the driving current to the light-emitting element LED according to a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on according to a first scan signal GW transferred through the first scan line SL1, and performs a switching operation of transferring a data signal Dm to a first node N1, the data signal DATA being transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, wherein the first scan signal GW is transferred through the first scan line SL1.

The fourth transistor T4 serves as a first initialization transistor and is electrically connected to the third scan line SL3 and the first initialization voltage line VIL1. The fourth transistor T4 may be turned on according to a third scan signal GI to initialize a voltage of the gate electrode of the first transistor T1 by transferring the first initialization voltage Vint to the gate electrode of the first transistor T1, wherein the third scan signal GI is transferred through the third scan line SL3. The third scan signal GI may correspond to a first scan signal of another pixel driving circuit disposed in a previous row of the relevant pixel driving circuit PC.

The fifth transistor T5 may be an operation control transistor, and the sixth transistor T6 may be an emission control transistor. The fifth transistor T5 and the sixth transistor T6 may be electrically connected to an emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit PC is electrically connected to signal lines and voltage lines. The signal lines may include a gate line such as, for example, the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may be configured to transfer the first initialization voltage Vint to the pixel driving circuit PC, wherein the first initialization voltage Vint initializes the first transistor T1. The second initialization voltage line VIL2 may be configured to transfer a second initialization voltage Vaint to the pixel driving circuit PC, wherein the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, wherein the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, wherein the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit disposed in a previous row of the relevant pixel driving circuit PC.

The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VIL2, and the sixth transistor T6. The seventh transistor T7 is turned on according to a second scan signal GB transferred through the second scan line SL2, and is configured to transfer the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display apparatus depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may prevent a black brightness from increasing when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

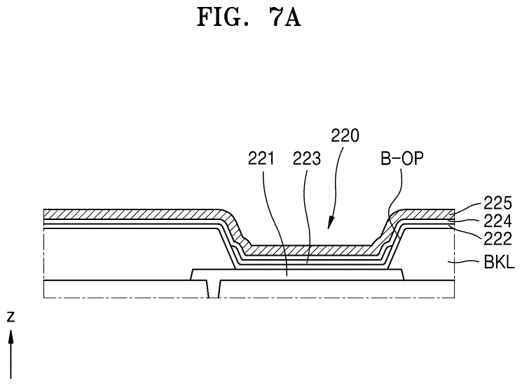

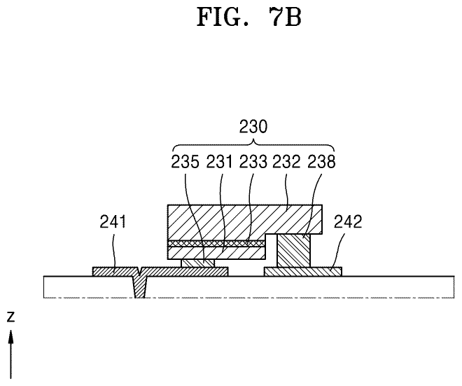

FIG. 7A is a schematic cross-sectional view of a light-emitting element of the display apparatus 1 according to an embodiment.

Referring to FIG. 7A, the light-emitting element according to an embodiment may include an organic light-emitting diode 220 including an organic material. The organic light-emitting diode 220 may include a first electrode 221 disposed on the insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may include an opening B-OP overlapping the central portion of the first electrode 221.

The first electrode 221 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a layer on/under the reflective layer, the layer including ITO, IZO, ZnO, AZO, or In₂O₃.

The emission layer 223 may include a polymer organic material or a low-molecular weight organic material emitting light having a preset color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. As an example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In₂O₃.

FIG. 7B is a schematic cross-sectional view of a light-emitting element of the display apparatus 1 according to an embodiment.

Referring to FIG. 7B, the light-emitting element according to an embodiment may be an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed on the same layer.

In an embodiment, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as, for example, GaN, AlN, AlGaN, InGaN, InN, InAlGaN, AlInN, and the like, and may be doped with a p-type dopant such as, for example, Mg, Zn, Ca, Sr, or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as, for example, GaN, AlN, AlGaN, InGaN, InN, InAlGaN, AlInN, and the like, and may be doped with an n-type dopant such as, for example, Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and be formed in a single quantum-well structure or a multi quantum-well structure. In some aspects, the intermediate layer 233 may include a quantum-wire structure or a quantum-dot structure.

Although it is described with reference to FIG. 7B that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer, and the second semiconductor layer 232 may include a p-type semiconductor layer.

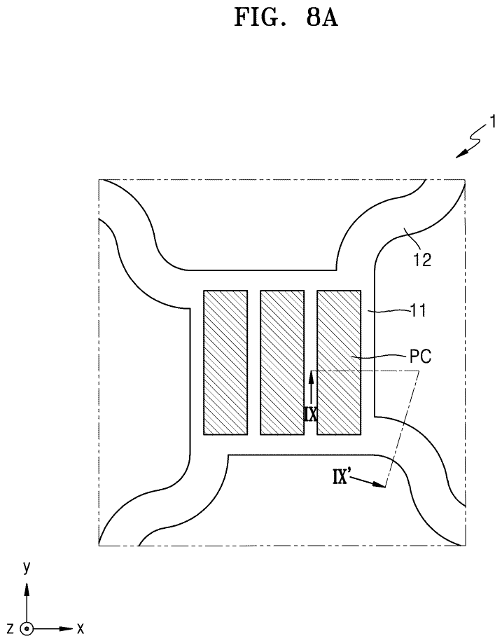

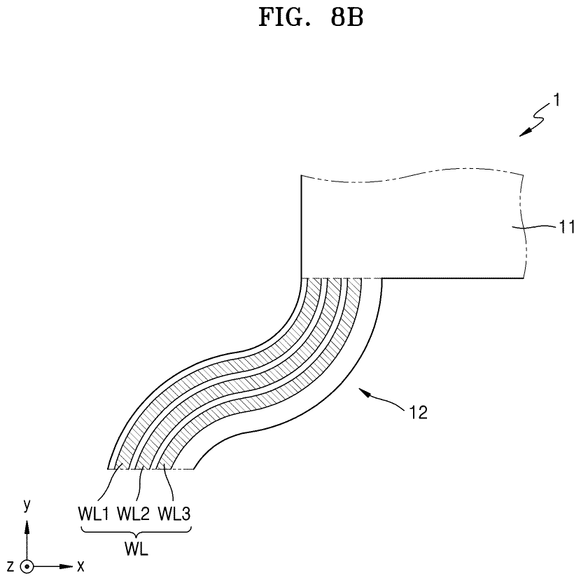

FIG. 8A is an enlarged plan view of the first island portion 11 of the display apparatus 1 according to an embodiment, and FIG. 8B is a plan view of an arrangement of the wiring WL on the first bridge portion 12 of the display apparatus 1 according to an embodiment.

Specifically, FIG. 8B is an enlarged plan view of a portion of the display apparatus 1 of FIG. 8A.

Referring to FIG. 8A, the first island portion 11 disposed in the display area DA may include the light-emitting element and the pixel driving circuit PC electrically connected thereto. As described herein, the pixel driving circuit PC may include the transistors and at least one capacitor. Although it is illustrated in FIG. 8A that three pixel driving circuits PC are disposed in the first island portion 11, the disclosure is not limited thereto. In another embodiment, the number of pixel driving circuits PC and the number of light-emitting elements disposed in the first island portion 11 may be one, two, or four or more.

Referring to FIG. 8B, the first bridge portion 12 may include a plurality of wirings WL electrically connected to the pixel driving circuits PC respectively disposed in adjacent first island portions 11. As described herein, the wirings WL may be signal lines (e.g., a gate line, a data line, and the like) configured to provide electrical signals, or voltage lines (e.g., a driving voltage line, an initialization voltage line, and the like) configured to provide voltages to transistors included in the pixel driving circuit PC of the first island portion 11. Although it is illustrated in FIG. 8B that a plurality of wirings WL, for example, first to third wirings WL1, WL2, and WL3 are disposed on the first bridge portion 12, the disclosure is not limited thereto. In another embodiment, one wiring WL may be disposed on the first bridge portion 12.

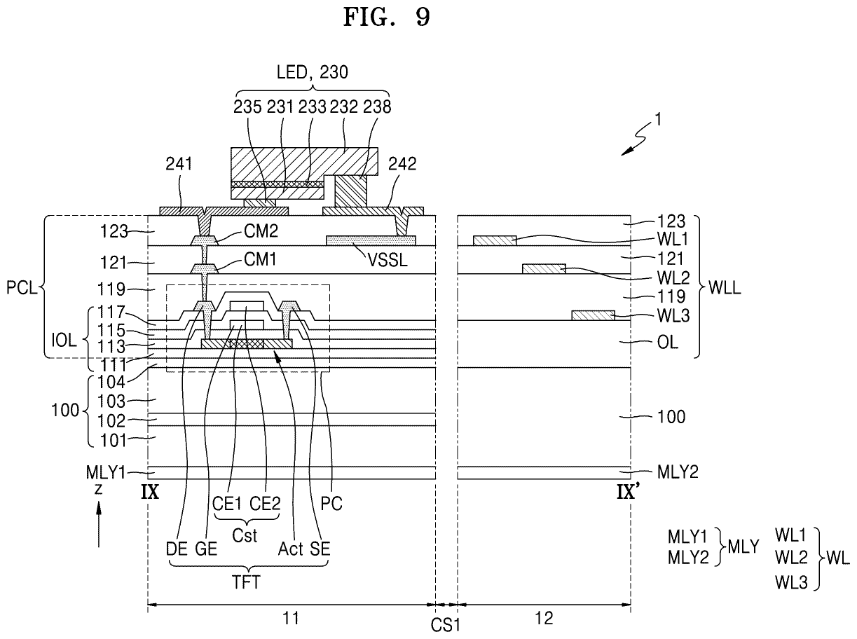

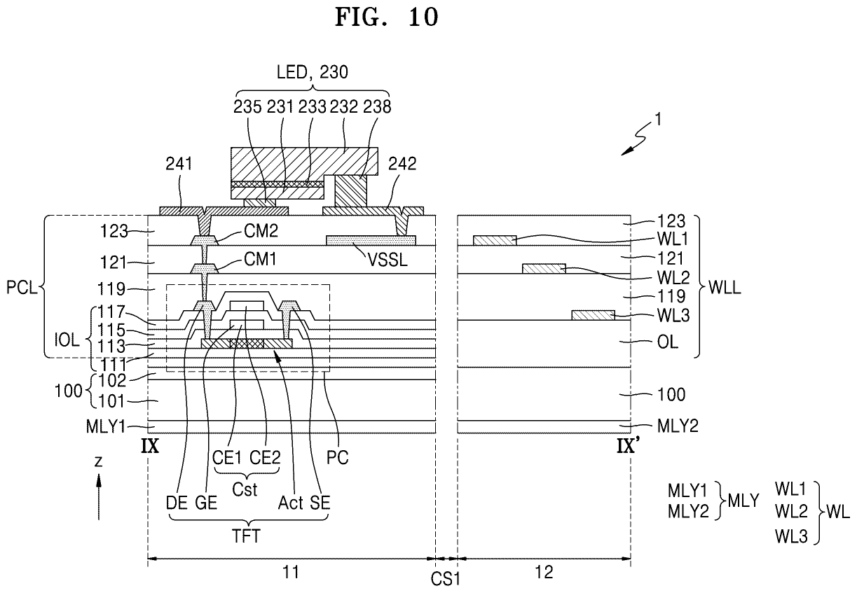

FIGS. 9 and 10 are schematic cross-sectional views of the display apparatus 1 according to an embodiment.

Specifically, FIGS. 9 and 10 are cross-sectional views of the display apparatus 1, taken along line IX-IX′ of FIG. 8A.

Referring to FIGS. 9 and 10, the display apparatus 1 may include a mask layer MLY, the substrate 100, the pixel circuit layer PCL, the wiring layer WLL, and a light-emitting diode LED.

The mask layer MLY may be disposed under the display apparatus 1. The mask layer MLY may be disposed in the first island portion 11 and the first bridge portion 12. The mask layer MLY may support the substrate 100, the pixel circuit layer PCL, the wiring layer WLL, and the light-emitting diode LED.

The mask layer MLY may include a first mask layer MLY1 and a second mask layer MLY2 disposed apart from each other. The first mask layer MLY1 and the second mask layer MLY2 may be disposed on the same layer. The first mask layer MLY1 may be disposed in the first island portion 11. The second mask layer MLY2 may be disposed in the first bridge portion 12. The first mask layer MLY1 and the second mask layer MLY2 may be disposed apart from each other, with the first opening CS1 between the first mask layer MLY1 and the second mask layer MLY2. That is, an opening may be formed in the mask layer MLY and overlap the first opening CS1.

The first mask layer MLY1 and the second mask layer MLY2 may include the same material. As an example, the mask layer MLY may include at least one of a transparent conductive oxide (TCO), metal, or a silicon oxide. An etching selectivity of a first base layer 101 with respect to the mask layer MLY may be greater than 1. As an example, an etching selectivity of the first base layer 101 with respect to the mask layer MLY may be 40 or more. However, this is just an example, and an etching selectivity between the mask layer MLY and the first base layer 101 is not limited thereto.

The substrate 100 may be disposed on the mask layer MLY. The substrate 100 may be disposed on the first mask layer MLY1 and the second mask layer MLY2. The substrate 100 overlapping the first mask layer MLY1 may be included in the first island portion 11. The substrate 100 overlapping the second mask layer MLY2 may be included in the first bridge portion 12. An opening may be formed in the substrate 100 and overlap the first opening CS1.

As illustrated in FIG. 9, in an embodiment, the substrate 100 disposed on the first mask layer MLY1 may include the first base layer 101, a first barrier layer 102, a second base layer 103, and a second barrier layer 104.

The first base layer 101 may be disposed on the first mask layer MLY1, the first barrier layer 102 may be disposed on the first base layer 101, the second base layer 103 may be disposed on the first barrier layer 102, and the second barrier layer 104 may be disposed on the second base layer 103. The first base layer 101 may be in contact with the first mask layer MLY1. The second barrier layer 104 may be in contact with the pixel circuit layer PCL. Each of the first barrier layer 102 and the second barrier layer 104 may overlap the first mask layer MLY1 and be apart from the second mask layer MLY2.

Each of the first base layer 101 and the second base layer 103 may include polymer resin including polyethersulfone, polyarylate, polyetherimide, polyethylene naphthalate, polyethylene terephthalate, polyphenylene sulfide, polyimide, polycarbonate, cellulose tri acetate, and cellulose acetate propionate. Each of the first barrier layer 102 and the second barrier layer 104 may include an inorganic insulating material such as, for example, silicon oxide, silicon nitride, or silicon oxynitride.

As illustrated in FIG. 10, in an embodiment, the substrate 100 disposed on the first mask layer MLY1 may include the first base layer 101, and the first barrier layer 102.

The first base layer 101 may be disposed on the first mask layer MLY1, and the first barrier layer 102 may be disposed on the first base layer 101. The first base layer 101 may be in contact with the first mask layer MLY1. The first barrier layer 102 may be in contact with the pixel circuit layer PCL. The first barrier layer 102 may overlap the first mask layer MLY1 and be apart from the second mask layer MLY2. Unlike the embodiment described with reference to FIG. 9, in the embodiment described with reference to FIG. 10, the second base layer 103 (see FIG. 9) and the second barrier layer 104 (see FIG. 9) may be omitted. The first mask layer MLY1 may perform the function of the second barrier layer 104 (see FIG. 9).

The first base layer 101 may include polymer resin such as, for example, polyethersulfone, polyarylate, polyetherimide, polyethylene naphthalate, polyethylene terephthalate, polyphenylene sulfide, polyimide, polycarbonate, cellulose tri acetate, and cellulose acetate propionate. The first barrier layer may include an inorganic insulating material such as, for example, silicon oxide, silicon nitride, or silicon oxynitride.

Each of the first base layer 101 and the second base layer 103 may include polymer resin including polyethersulfone, polyarylate, polyetherimide, polyethylene naphthalate, polyethylene terephthalate, polyphenylene sulfide, polyimide, polycarbonate, cellulose tri acetate, and cellulose acetate propionate. Each of the first barrier layer 102 and the second barrier layer 104 may include an inorganic insulating material such as, for example, silicon oxide, silicon nitride, or silicon oxynitride.

The pixel circuit layer PCL may be disposed on the substrate 100 and overlap the first mask layer MLY1. The pixel circuit layer PCL may include an inorganic insulating layer IOL and the pixel driving circuit PC. As an example, the inorganic insulating layer IOL may include the buffer layer 111, a gate insulating layer 113, a first interlayer insulating layer 115, and a second interlayer insulating layer 117. As an example, the pixel driving circuit PC may include a thin-film transistor TFT and a storage capacitor Cst.

The buffer layer 111 may be disposed on the substrate 100, and the pixel driving circuit PC may be disposed on the buffer layer 111. The buffer layer 111 may include an inorganic insulating material such as, for example, silicon oxide, silicon nitride, or silicon oxynitride.

The thin-film transistor TFT may include a semiconductor layer Act, a gate electrode GE, a source electrode SE, and a drain electrode DE. Although FIGS. 9 and 10 illustrate an example of a top-gate type thin-film transistor in which the gate electrode GE is disposed on the semiconductor layer Act, with the gate insulating layer 113 between the gate electrode GE and the semiconductor layer Act, the thin-film transistor TFT may be a bottom-gate type thin-film transistor in another embodiment.

The semiconductor layer Act may include polycrystalline silicon. Alternatively, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The gate insulating layer 113 between the semiconductor layer Act and the gate electrode GE may include an inorganic insulating material such as, for example, silicon oxide, nitrogen oxide, silicon oxynitride, aluminum oxide, or titanium oxide. The gate insulating layer 113 may include a single layer or a multi-layer including the above materials.

The source electrode SE and the drain electrode DE may be located on the same layer, for example, the second interlayer insulating layer 117 and may include the same material. The source electrode SE and the drain electrode DE may include a conductive material and include a single layer or a multi-layer. The second interlayer insulating layer 117 may include an inorganic insulating material such as, for example, silicon oxide, nitrogen oxide, silicon oxynitride, aluminum oxide, titanium oxide, and include a single layer or a multi-layer including the above materials.

The storage capacitor Cst may include the first electrode CE1 and the second electrode CE2 overlapping each other, with the first interlayer insulating layer 115 between the first electrode CE1 and the second electrode CE2. The storage capacitor Cst may overlap the thin-film transistor TFT. With regard to this, it is illustrated in FIGS. 9 and 10 that the gate electrode GE of the thin-film transistor TFT serves as the first electrode CE1 of the storage capacitor Cst. In another embodiment, the storage capacitor Cst may not overlap the thin-film transistor TFT. The storage capacitor Cst may be covered by a second interlayer insulating layer 207. The second electrode CE2 of the storage capacitor Cst may include a conductive material and include a single layer or a multi-layer. The first interlayer insulating layer 115 may be disposed between the gate insulating layer 113 and the second interlayer insulating layer 117. The first interlayer insulating layer 115 may include an inorganic insulating material such as, for example, silicon oxide, nitrogen oxide, silicon oxynitride, aluminum oxide, titanium oxide, and include a single layer or a multi-layer including the above materials.

As an example, the pixel circuit layer PCL may include a first organic insulating layer 119, a second organic insulating layer 121, and a third organic insulating layer 123. The first organic insulating layer 119 may be disposed on the second interlayer insulating layer 117, and the second organic insulating layer 121 may be disposed on the first organic insulating layer 119. Each of the first organic insulating layer 119 and the second organic insulating layer 121 may include an organic insulating material such as, for example, polyimide.

The second voltage line VSSL may be disposed on the second organic insulating layer 121, and the third organic insulating layer 123 may be disposed on the second organic insulating layer 121 and the second voltage line VSSL. The third organic insulating layer 123 may include an organic insulating material such as, for example, polyimide. The second voltage line VSSL may include a conductive material and include a single layer or a multi-layer.

The first electrode pad 241 and the second electrode pad 242 may be disposed on the third organic insulating layer 123. The first electrode pad 241 may be electrically connected to the thin-film transistor TFT through a first connection electrode CM1 between the first organic insulating layer 119 and the second organic insulating layer 121, and a second connection electrode CM2 between the second organic insulating layer 121 and the third organic insulating layer 123.

The light-emitting diode LED may be disposed on the pixel circuit layer PCL. The light-emitting diode LED may include the organic light-emitting diode 220 (see FIG. 7A) described with reference to FIG. 7A and/or the inorganic light-emitting diode 230 described with reference to FIG. 7B. Hereinafter, description is made on the assumption that the light-emitting diode LED includes the inorganic light-emitting diode 230.

The substrate 100 disposed on the second mask layer MLY2 may include the same material as a material of at least one of the first base layer 101 and the second base layer 103. As an example, the substrate 100 disposed on the second mask layer MLY2 may include polymer resin including polyethersulfone, polyarylate, polyetherimide, polyethylene naphthalate, polyethylene terephthalate, polyphenylene sulfide, polyimide, polycarbonate, cellulose tri acetate, and cellulose acetate propionate. Although it is illustrated in FIGS. 9 and 10 that the substrate 100 disposed on the second mask layer MLY2 has a single-layered structure, this is just an example and the substrate 100 disposed on the second mask layer MLY2 may have the same stack structure as a stack structure of the substrate 100 disposed on the first mask layer MLY1.

The wiring layer WLL may be disposed on the substrate 100 and overlap the second mask layer MLY2. The wiring layer WLL may include an insulating layer OL, the first organic insulating layer 119, the second organic insulating layer 121, the third organic insulating layer 123, and the wiring WL.

The inorganic insulating layer IOL may be disposed such that the inorganic insulating layer IOL is not disposed on the substrate 100, and the insulating layer OL, the first organic insulating layer 119, and the second organic insulating layer 121 may be disposed on the substrate 100. The insulating layer OL may include an organic insulating material such as, for example, polyimide. In an embodiment, the insulating layer OL may have a thickness corresponding to the inorganic insulating layer IOL. In an embodiment, the insulating layer OL may be omitted.

A plurality of wirings WL, for example, the first to third wirings WL1, WL2, and WL3 may be disposed on different layers and be electrically connected to the same pixel driving circuit PC. As an example, the first wiring WL1 may be disposed between the second organic insulating layer 121, the second wiring WL2 may be disposed between the first organic insulating layer 119 and the second organic insulating layer 121, and the third wiring WL3 may be disposed between the insulating layer OL and the first organic insulating layer 119. However, the disclosure is not limited thereto, and in another embodiment, at least some of the first to third wirings WL1, WL2, and WL3 may be disposed on the same layer.

In this structure, the pixel circuit layer PCL and the wiring layer WLL may be disposed on the same layer. The pixel circuit layer PCL may be disposed in the first island portion 11. The wiring layer WLL may be disposed in the first bridge portion 12. The pixel circuit layer PCL and the wiring layer WLL may be disposed apart from each other, with the first opening CS1 between the pixel circuit layer PCL and the wiring layer WLL. That is, an opening may be formed in the pixel circuit layer PCL and the wiring layer WLL and overlap the first opening CS1. In this case, in a cross-sectional view, the width of the first mask layer MLY1 may be equal to the width of the pixel circuit layer PCL. In a cross-sectional view, the width of the second mask layer MLY2 may be equal to the width of the wiring layer WLL.

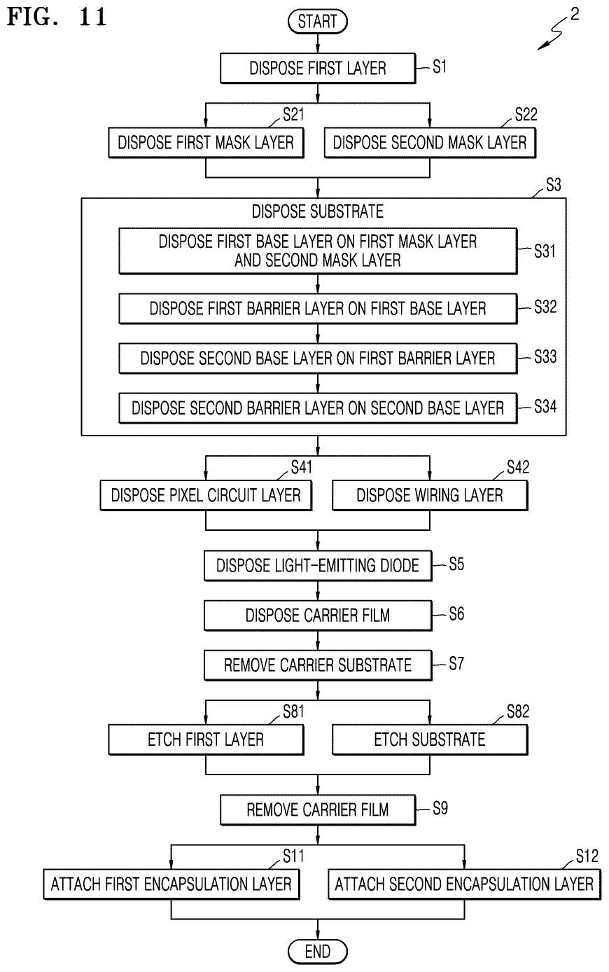

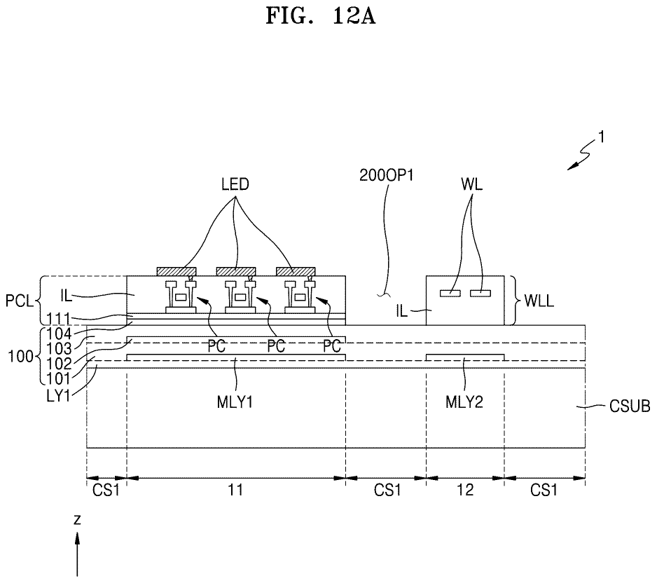

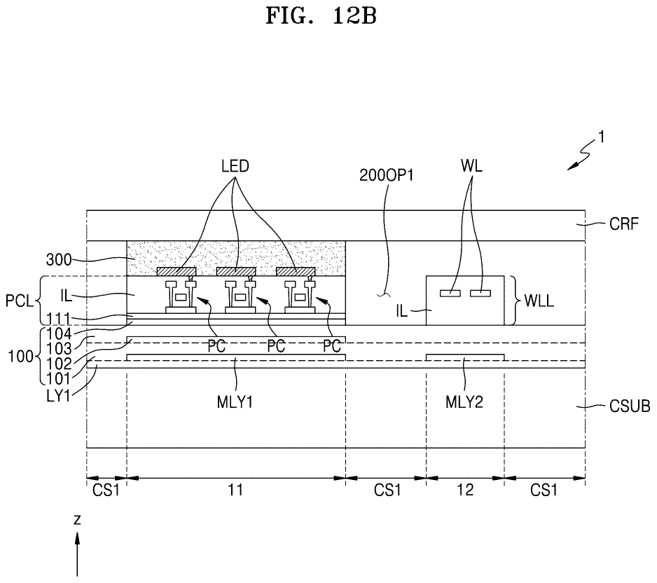

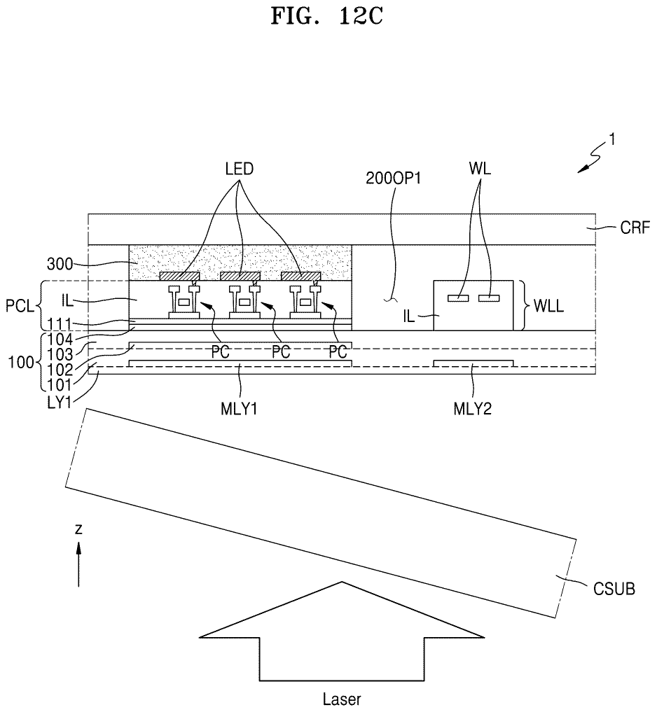

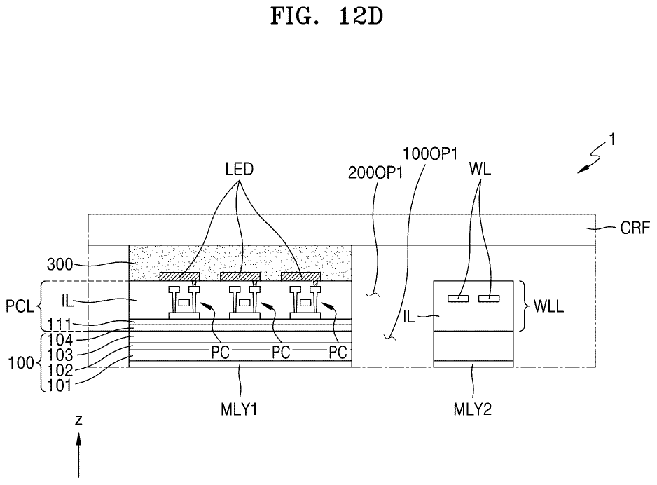

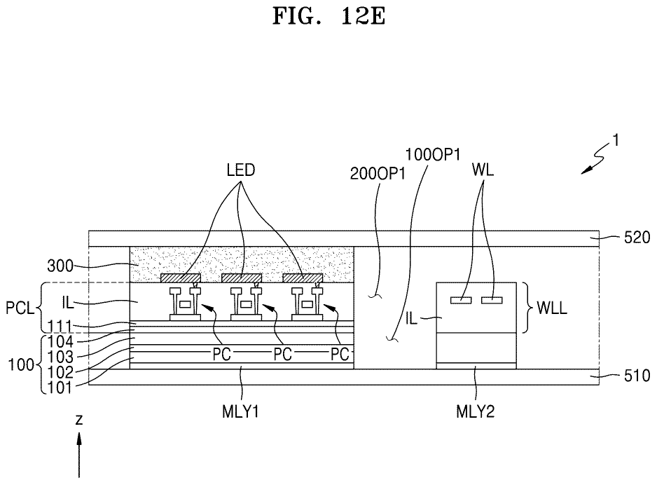

FIG. 11 is a schematic flowchart illustrating a method 2 of manufacturing a display apparatus according to an embodiment, and FIGS. 12A to 12E are schematic cross-sectional views of the display apparatus 1 according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, and the like in accordance with example aspects described herein.

In FIG. 11 and FIGS. 12A to 12E, the same reference numerals as those of FIGS. 9 and 10 denote the same members, and thus, repeated descriptions thereof are omitted.

Referring to FIGS. 11 and 12A, the method 2 of manufacturing a display apparatus may include disposing (S1) a first layer LY1 on a carrier substrate CSUB, disposing (S21) a first mask layer MLY1 on the first layer LY1, disposing (S22) a second mask layer MLY2 on the first layer LY1, disposing (S3) the substrate 100 on the first layer LY1, disposing (S41), on the substrate 100, a pixel circuit layer PCL which overlaps the first mask layer MLY1, disposing (S42), on the substrate 100, a wiring layer WLL which overlaps the second mask layer MLY2, and disposing (S5) a light-emitting diode LED on the pixel circuit layer PCL.

In the operation S1 of disposing the first layer LY1 on the carrier substrate CSUB, the first layer LY1 may be disposed in the first opening CS1, the first island portion 11, and the first bridge portion 12 entirely. The carrier substrate CSUB may support the first layer LY1 and the substrate 100 during the process, and may include glass.

In the operation S21 of disposing the first mask layer MLY1, the first mask layer MLY1 may overlap the first island portion 11 and be apart from the first bridge portion 12 and the first opening CS1. In the operation S22 of disposing the second mask layer MLY2, the second mask layer MLY2 may overlap the first bridge portion 12 and be apart from the first island portion 11 and the first opening CS1. The first mask layer MLY1 and the second mask layer MLY2 may be apart from each other. The method 2 may include simultaneously performing the operation S21 of disposing the first mask layer MLY1 and the operation S22 of disposing the second mask layer MLY2.

In the operation S3 of disposing the substrate 100, the substrate 100 may cover the first mask layer MLY1 and the second mask layer MLY2. The operation S3 of disposing the substrate 100 may include disposing (S31), on the first mask layer MLY1 and the second mask layer MLY2, the first base layer 101, disposing (S32), on the first base layer 101, the first barrier layer 102, disposing (S33), on the first barrier layer 102, the second base layer 103, and disposing (S34), on the second base layer 103, the second barrier layer 104.

In the operation S31 of disposing, on the first mask layer MLY1 and the second mask layer MLY2, the first base layer 101, the first base layer 101 may be disposed in the first opening CS1, the first island portion 11, and the first bridge portion 12 entirely. In the operation S32 of disposing, on the first base layer 101, the first barrier layer 102, the first barrier layer 102 may overlap the first island portion 11 and be apart from the first bridge portion 12 and the first opening CS1. In the operation S33 of disposing, on the first barrier layer 102, the second base layer 103, the second base layer 103 may be disposed in the first opening CS1, the first island portion 11, and the first bridge portion 12 entirely. The second base layer 103 may be disposed such that the second base layer 103 covers the first barrier layer 102. In the operation S34 of disposing, on the second base layer 103, the second barrier layer 104, the second barrier layer 104 may overlap the first island portion 11 and be apart from the first bridge portion 12 and the first opening CS1. The first layer LY1, the first base layer 101, and the second base layer 103 may include the same material.

In the operation S41 of disposing the pixel circuit layer PCL, the pixel circuit layer PCL may overlap the first island portion 11 and be apart from the first bridge portion 12 and the first opening CS1. In the operation S42 of disposing the wiring layer WLL, the pixel circuit layer PCL may overlap the first bridge portion 12 and be apart from the first island portion 11 and the first opening CS1. The pixel circuit layer PCL and the wiring layer WLL may be apart from each other, with the first opening CS1 between the pixel circuit layer PCL and the wiring layer WLL.

The method 2 may include simultaneously performing the operation S41 of disposing the pixel circuit layer PCL and the operation S42 of disposing the wiring layer WLL. Specifically, an operation of disposing the insulating layer IL in the first opening CS1, the first island portion 11, and the first bridge portion 12 entirely, may be performed, and then an operation of etching a portion of the insulating layer IL overlapping the first opening CS1 may be performed.

Referring to FIGS. 11 and 12B, the method 2 of manufacturing a display apparatus may include disposing (S6), on a light-emitting diode LED, a carrier film CRF.

The insulating layer IL may be disposed on the light-emitting diode LED. The insulating layer IL may be disposed on the light-emitting diode LED and may protect the light-emitting diode LED from external force and/or moisture transmission. The insulating layer IL may include an inorganic encapsulation layer and/or an organic encapsulation layer. In an embodiment, the insulating layer IL may include a structure in which an inorganic encapsulation layer including an inorganic insulating material, an organic encapsulation layer including an organic insulating material, and an inorganic encapsulation layer including an inorganic insulating material are stacked. In an embodiment, the insulating layer IL may include an organic material such as, for example, resin. In an embodiment, the insulating layer IL may include urethane epoxy acrylate. The insulating layer IL may include a photosensitive material, for example, a photoresist. The insulating layer IL may include an organic material. The insulating layer IL may be formed through inkjet printing or patterning after coating.

The carrier substrate CSUB may be disposed on the insulating layer IL and may cover the first island portion 11 and the first bridge portion 12. Although not illustrated in FIG. 12B, the carrier film CRF may be attached by an adhesive layer. The carrier film CRF is a protective film that facilitates handing during subsequent processes and may include a flexible plastic material such as, for example, polyethylene terephthalate (PET) or polyimide.

Referring to FIGS. 11 and 12C, the method 2 of manufacturing a display apparatus may include removing (S7) the carrier substrate CSUB. The carrier substrate CSUB may be separated from the substrate 100 in a laser-lift off method by emitting a laser beam toward the lower portion of the carrier substrate CSUB and irradiating the lower portion of the carrier substrate CSUB using the laser beam. Alternatively, the carrier substrate CSUB may be separated from the substrate 100 using known physical or chemical methods.

Referring to FIGS. 11, 12C, and 12D, the method 2 of manufacturing a display apparatus may include etching (S81) the first layer LY1 and etching (S82) the substrate 100.

The etching of the first layer LY1 and the substrate 100 may be performed under the display apparatus 1 using dry etching that uses an etching gas, or wet etching that uses an etching solution.

During the process of etching the substrate 100, the first mask layer MLY1 and the second mask layer MLY2 may be hardly etched. For example, during the process, a portion of the substrate 100 overlapping the first mask layer MLY1 and the second mask layer MLY2 may not be etched. A portion of the substrate 100 apart from the first mask layer MLY1 and the second mask layer MLY2 may be removed. The method 2 may include simultaneously performing the operation S81 of etching the first layer LY1 and the operation S82 of etching the substrate 100.

Referring to FIGS. 11, 12D, and 12E, the method 2 of manufacturing a display apparatus may include removing (S9) the carrier film CRF, attaching (S11) a first encapsulation layer 510 to the first mask layer MLY1 and the second mask layer MLY2, and disposing (S12) a second encapsulation layer 520 on the light-emitting diode LED.

In an embodiment, after the operation S9 of removing the carrier film CRF, the operation S11 of attaching the first encapsulation layer 510 and the operation S12 of disposing the second encapsulation layer 520 may be performed. However, this is just one embodiment, and in some other embodiments, after the operation S11 of attaching the first encapsulation layer 510, the operation S9 of removing the carrier film CRF and the operation S12 of disposing the second encapsulation layer 520 may be performed.

The first encapsulation layer 510 may include a stretchable sheet. The first encapsulation layer 510 may include an elastomer film, a polydimethylsiloxane (PDMS) film, a silicon film, or the like. The first encapsulation layer 510 may be attached to the lower surface of the first mask layer MLY1 and the lower surface of the second mask layer MLY2 by a lamination process.

The second encapsulation layer 520 may include a stretchable sheet. The second encapsulation layer 520 may include an elastomer film, a polydimethylsiloxane (PDMS) film, a silicon film, or the like. The second encapsulation layer 520 may include the same material as a material of the first encapsulation layer 510. The second encapsulation layer 520 may be attached to the insulating layer IL.

According to the above embodiment, the operation of etching the pixel circuit layer PCL and the wiring layer WLL (specifically, the insulating layer IL), and the operation of etching the substrate 100 (specifically, the first base layer 101 and the second base layer 103) may be performed separately (i.e., not simultaneously). The pixel circuit layer PCL and the wiring layer WLL are etched first, and then the substrate 100 may be etched. Such a process may prevent the pixel circuit layer PCL and the substrate 100 from being exposed to the etching process at a time for a long time. Accordingly, a phenomenon that a step difference in height between the pixel circuit layer PCL and the wiring layer WLL is formed may be reduced. In some aspects, a phenomenon of damage to the pixel driving circuit PC and the wiring WL due to a long-term etching process may be reduced.

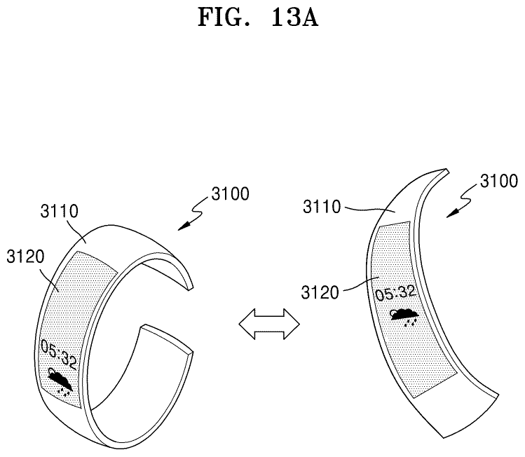

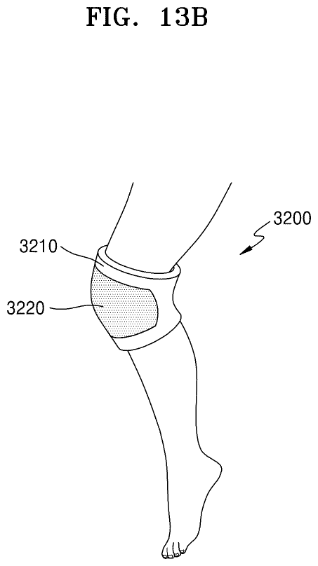

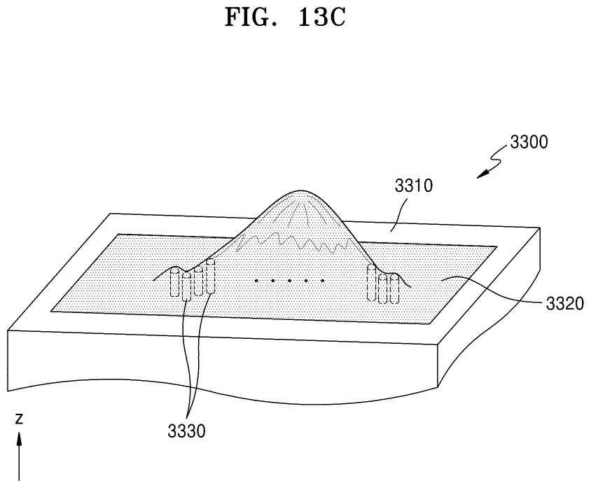

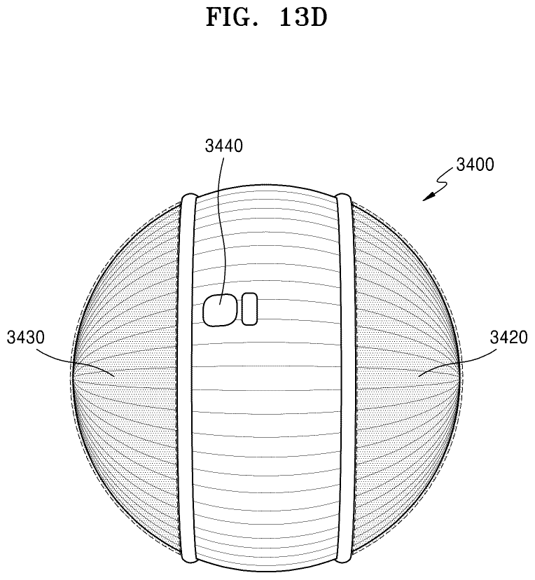

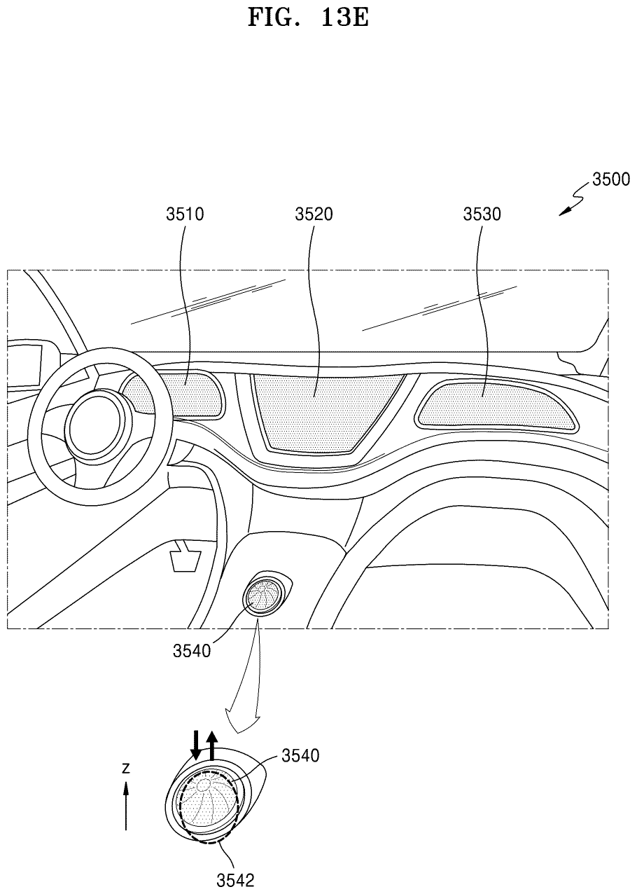

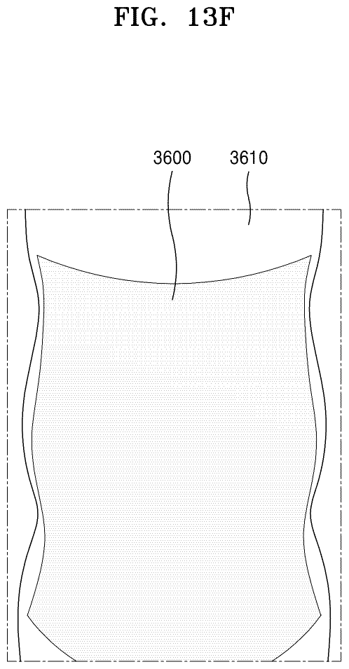

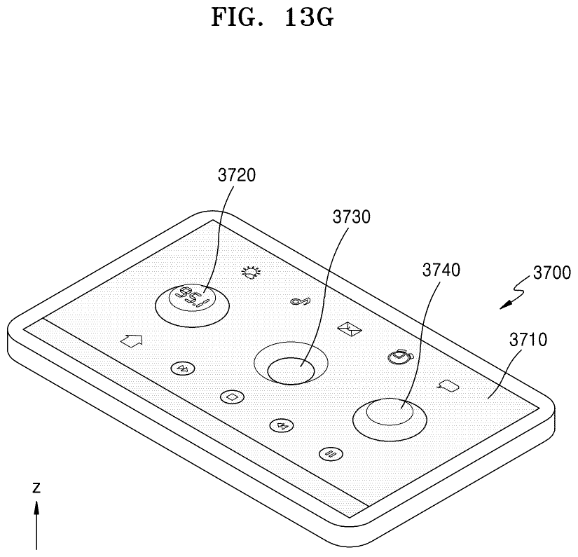

FIGS. 13A to 13G are schematic perspective views of the electronic apparatus including the display apparatus according to an embodiment.

The stretchable display apparatus 1 according to the above embodiments may be used in various electronic apparatuses that may display images. Here, the electronic apparatuses represent apparatuses that may display preset images using electricity.

Referring to FIG. 13A, the stretchable display apparatus according to an embodiment may be utilized in a wearable electronic apparatus 3100 that may be worn on a portion of a user's body. The wearable electronic apparatus 3100 may include a body portion 3110 and a display portion 3120 provided to the body portion 3110. A stretchable display apparatus according to embodiments may be used as the display portion 3120 of the wearable electronic apparatus 3100. As illustrated in FIG. 13A, the wearable electronic apparatus 3100 may be transformed. In an embodiment, the wearable electronic apparatus 3100 may be used as a smartwatch or a smartphone according to a user's selection.

FIG. 13B illustrates a medical electronic apparatus 3200. In an embodiment, the medical electronic apparatus 3200 may include a body portion 3210 and a light-emitting portion 3220. A stretchable display apparatus according to embodiments may be used as the light-emitting portion 3220 of the medical electronic apparatus 3200. The light-emitting portion 3220 may emit light (e.g., infrared rays, visible rays, and the like) in a preset wavelength band to a patient's body. In an embodiment, the body portion 3210 may include a stretchable fiber material and have a structure that may be worn on the body of a user of the light-emitting portion.

FIG. 13C illustrates an educational electronic apparatus 3300. In an embodiment, the educational electronic apparatus may include a display portion 3320 provided inside a frame 3310. The display portion 3320 may be used as the stretchable display apparatus according to the embodiments. An image such as, for example, a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In an embodiment, a portion of the display portion 3320 may be configured to sequentially change its height in a direction in which the lava flows, thereby illustrating the movement of the lava three dimensionally. The educational electronic apparatus 3300 may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 13C describes the educational electronic apparatus 3300, the purpose thereof is not limited thereto as far as the educational electronic apparatus 3300 provides preset image information.

Although FIGS. 13A to 13C describe an electronic apparatus having a variable shape, the disclosure is not limited thereto. As in embodiments described herein, the stretchable display apparatus according to embodiments may be used in an electronic apparatus in which a portion (e.g., screen) that may display images is fixed.

FIG. 13D illustrates a robot 3400 as an electronic apparatus according to an embodiment. The robot 3400 may recognize a movement or object using a camera portion 3440 and express preset images to a user through display portions 3420 and 3430. In an embodiment, because the stretchable display apparatuses according to an embodiment may be stretched in various directions as described herein, the stretchable display apparatuses may be assembled to a body frame having a hemispherical shape, and thus, the robot 3400 may include the display portions 3420 and 3430 of a hemispherical shape.

FIG. 13E illustrates a vehicle display apparatus 3500 as an electronic apparatus according to an embodiment. The vehicle display apparatus 3500 may include a cluster 3510, a center information display (CID) 3520, and/or a passenger display. Because the stretchable display apparatus according to an embodiment may be stretched in various directions, the display apparatus may be used in the cluster 3510, the CID 3520, and/or the passenger display without being restricted by the shape of an internal frame of the vehicle.

Although it is illustrated in FIG. 13E that the cluster 3510, the CID 3520, and/or the passenger display are separated from each other, the disclosure is not limited thereto. In another embodiment, two or more selected from the cluster 3510, the CID 3520, and the passenger display may be integrally connected.

In another embodiment, the vehicle display apparatus 3500 may include a button 3540 that may express preset images. Referring to an enlarged view of FIG. 13E, the button 3540 of a hemispherical shape may include an object 3542 and a stretchable display apparatus disposed on the object 3542, wherein the object 3542 provides the feel of a button while moving in the z direction or −z-direction. In an embodiment, in the case where the object 3542 has a three-dimensionally round surface, the stretchable display apparatus may also have a three-dimensionally round surface.

FIG. 13F illustrates an electronic apparatus according to an embodiment is an electronic apparatus 3600 for advertising or display. In an embodiment, the electronic apparatus 3600 for advertising or display may be installed on structure 3610 that is fixed such as, for example, a wall or pole. In the case where the structure 3610 includes an uneven surface as illustrated in FIG. 13F, the electronic apparatus 3600 for advertising or display may be also disposed along the uneven surface of the structure 3610. In an embodiment, the electronic apparatus 3600 for advertising or display may be installed on the structure 3610 using a heat shrink film.

FIG. 13G illustrates the electronic apparatus according to an embodiment is a controller 3700. The controller 3700 may include an image-type button. As an example, the controller 3700 may include a first button region 3720, a second button region 3730, and a third button region 3740 in which a portion of the display portion 3710 protrudes in the z direction or protrudes in the −z direction (or is recessed in the z direction). In an embodiment, the first button region 3720 and the third button region 3740 may protrude in the z direction, and the second button region 3730 may protrude in the −z direction (or be recessed in the z direction).

According to an embodiment, a display apparatus capable of preventing damage due to stress concentration and being stretched in various directions may be provided. However, the scope of the disclosure is not limited by this effect.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a mask layer comprising a first mask layer and a second mask layer disposed apart from each other;
a substrate disposed on the first mask layer and the second mask layer;
a pixel circuit layer which is disposed on the substrate and overlaps the first mask layer;
a wiring layer which is disposed on the substrate and overlaps the second mask layer; and
a light-emitting diode disposed on the pixel circuit layer.

2. The display apparatus of claim 1, wherein, in a cross-sectional view, a width of the first mask layer is equal to a width of the pixel circuit layer.

3. The display apparatus of claim 1, wherein, in a cross-sectional view, a width of the second mask layer is equal to a width of the wiring layer.

4. The display apparatus of claim 1, wherein the substrate comprises:
a first base layer; and
a first barrier layer disposed on the first base layer.

5. The display apparatus of claim 4, wherein:
the first barrier layer is in contact with the pixel circuit layer, and
the first base layer is in contact with the mask layer.

6. The display apparatus of claim 4, wherein the substrate further comprises:
a second base layer disposed on the first barrier layer; and
a second barrier layer disposed on the second base layer,
wherein:
the second barrier layer is in contact with the pixel circuit layer, and
the first base layer is in contact with the mask layer.

7. The display apparatus of claim 4, wherein an etching selectivity of the first base layer with respect to the mask layer is 40 or more.

8. The display apparatus of claim 4, wherein the first barrier layer overlaps the first mask layer and is apart from the second mask layer.

9. The display apparatus of claim 1, wherein the mask layer comprises at least one of a transparent conductive oxide (TCO), metal, or a silicon oxide.

10. An electronic apparatus comprising:
a mask layer comprising a first mask layer and a second mask layer disposed apart from each other;
a substrate disposed on the first mask layer and the second mask layer;
a pixel circuit layer which is disposed on the substrate and overlaps the first mask layer;
a wiring layer which is disposed on the substrate and overlaps the second mask layer; and
a light-emitting diode disposed on the pixel circuit layer,
wherein, in a cross-sectional view, a width of the first mask layer is equal to a width of the pixel circuit layer, and a width of the second mask layer is equal to a width of the wiring layer.

11. A method of manufacturing a display apparatus, the method comprising:
disposing a first layer on a carrier substrate;
disposing a first mask layer on the first layer;
disposing, on the first layer, a second mask layer which is apart from the first mask layer;
disposing, on the first layer, a substrate which covers the first mask layer and the second mask layer;
disposing, on the substrate, a pixel circuit layer which overlaps the first mask layer;
disposing, on the substrate, a wiring layer which overlaps the second mask layer;
disposing a light-emitting diode on the pixel circuit layer;
disposing a carrier film on the light-emitting diode;
removing the carrier substrate;
etching the first layer;
etching the substrate such that a portion of the substrate apart from the first mask layer and the second mask layer is removed; and
removing the carrier film.

12. The method of claim 11, wherein the disposing of the substrate comprises:
disposing a first base layer on the first mask layer and the second mask layer;
and disposing, on the first base layer, a first barrier layer which overlaps the first mask layer.

13. The method of claim 12, wherein an etching selectivity of the first base layer with respect to the first mask layer is 40 or more.

14. The method of claim 12, wherein the disposing of the substrate further comprises:
disposing, on the first base layer, a second base layer which covers the first barrier layer; and
disposing, on the second base layer, a second barrier layer which overlaps the first mask layer.

15. The method of claim 11, further comprising:
attaching a first encapsulation layer to the first mask layer and the second mask layer; and
disposing a second encapsulation layer on the light-emitting diode.

16. The method of claim 11, wherein the disposing of the first mask layer and the disposing of the second mask layer are simultaneously performed.

17. The method of claim 11, wherein the disposing of the pixel circuit layer and the disposing of the wiring layer are simultaneously performed.

18. The method of claim 11, wherein the etching of the first layer and the etching of the substrate are simultaneously performed.

19. The method of claim 11, wherein, in a cross-sectional view, a width of the first mask layer is equal to a width of the pixel circuit layer.

20. The method of claim 11, wherein, in a cross-sectional view, a width of the second mask layer is equal to a width of the wiring layer.
